(19) United States
(12) Patent Application Publication
(10) Pub. No.: US 2024/0329119 A1
(43) Pub. Date: Oct. 3, 2024

(54) INTEGRATED CIRCUIT AND INTEGRATED CIRCUIT TESTING METHOD

(71) Applicant: Realtek Semiconductor Corp., HsinChu (TW)

(72) Inventors: Yu-Chen Hsieh, HsinChu (TW); Jian-Ru Lin, HsinChu (TW); Tsung-Yen Tsai, HsinChu (TW); Yung-Tai Chen, HsinChu (TW); Yen-Wei Liu, HsinChu (TW)

(73) Assignee: Realtek Semiconductor Corp., HsinChu (TW)

(21) Appl. No.: 18/621,026

(22) Filed: Mar. 28, 2024

(30) Foreign Application Priority Data
Mar. 31, 2023 (TW) 112112443

(51) Int. Cl. G01R 31/28; G01R 31/317

(52) U.S. Cl. CPC G01R 31/2875; G01R 31/31727

(57) ABSTRACT

An IC, comprising: a package; a target circuit; and a heating circuit, configured to receive a heating signal to heat at least testing portion of the target circuit to a first predetermined temperature based on the heating signal. The target circuit and the heating circuit are within the package. An IC testing method using such IC is also disclosed.

### BACKGROUND OF THE INVENTION

### 1. Field of the Invention

The present invention relates to an IC (Integrated Circuit) and an IC testing method, and particularly relates to an IC and an IC testing method which can heat an IC by a simple mechanism and perform an IC test to test the IC.

### 2. Description of the Prior Art

In conventional IC testing methods, the IC is heated to detect whether the IC can operate normally at higher temperatures. However, in these IC testing methods, it is necessary to use a dedicated heating machine, a heating gun or a heating box to heat the entire IC. Such method not only requires additional equipment, but also takes a long time to heat the entire IC. After the IC reaches the required temperature and is tested, it takes more time waiting for the IC to cool down before further performing other IC tests. This also substantially increases the overall testing time.

### SUMMARY OF THE INVENTION

One objective of the present invention is to provide an IC with a heating circuit which can provide a heating function for testing the IC.

Another objective of the present invention is to provide an IC testing method for testing an IC with a heating circuit which can provide a heating function for testing the IC.

One embodiment of the present invention discloses an IC, comprising: a package; a target circuit; and a heating circuit, configured to receive a heating signal to heat at least a testing portion of the target circuit to a first predetermined temperature. The target circuit and the heating circuit are within the package.

Another embodiment of the present invention discloses an IC testing method, for testing an IC comprising a target circuit and a heating circuit, comprising: (a) generating a heating signal by a testing machine; (b) receiving a heating signal by the heating circuit to heat at least testing portion of the target circuit to a first predetermined temperature; and (c) testing the testing portion by the testing machine within a predetermined time after heating the testing portion to the first predetermined temperature.

In view of above-mentioned embodiments, a heating circuit with a simpler structure can be provided in the IC to heat the testing portion without heating the entire IC through other heating machines or heating equipment. Therefore, the IC and the IC testing method provided by the present invention can reduce the complexity of IC testing, reduce the time of IC testing, and reduce the cost of IC testing.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a block diagram of an IC according to one embodiment of the present invention.

FIG. 2 is a schematic diagram of an IC according to one embodiment of the present invention.

FIG. 3 is a block diagram illustrating a target circuit according to one embodiment of the present invention.

FIG. 4 is a circuit diagram illustrating a heating circuit according to one embodiment of the present invention.

FIG. 5 is a schematic diagram illustrating an example for testing an IC provided by the present invention via a testing machine.

FIG. 6 is a flow chart illustrating an IC testing method according to one embodiment of the present invention.

### DETAILED DESCRIPTION

In the following descriptions, several embodiments are provided to explain the concept of the present application. It will be appreciated that the system, the device, the apparatus or the module depicted in following embodiments can be implemented by hardware (ex. circuit) or the combination of hardware and software (ex. a processing unit executing at least one program). The term “first”, “second”, “third” in following descriptions are only for the purpose of distinguishing different one elements, and do not mean the sequence of the elements. For example, a first device and a second device only mean these devices can have the same structure but are different devices.

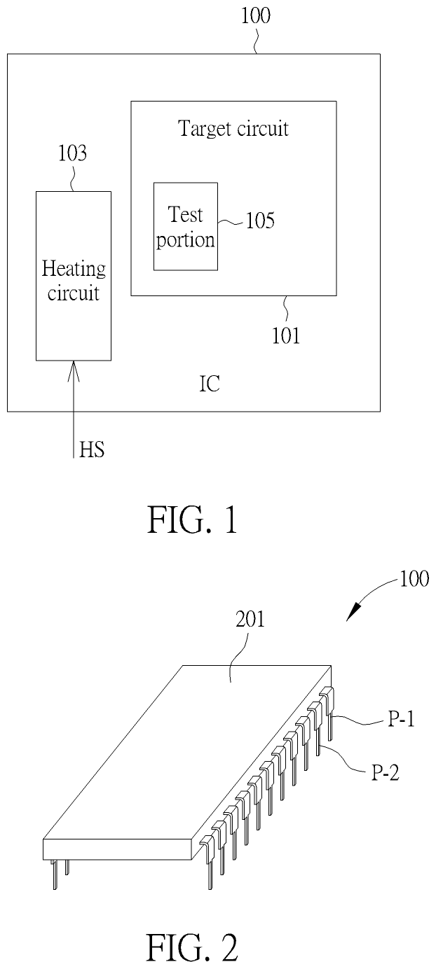

FIG. 1 is a block diagram of an IC according to one embodiment of the present invention. As shown in FIG. 1, the IC 100 comprises a target circuit 101 and a heating circuit 103. The heating circuit 103 is configured to receive a heating signal HS and heat a testing portion 105 of the target circuit 101 to a first predetermined temperature based on the heating signal HS. Please also note that the heating circuit 103 can also heat two or more testing portions at the same time. Both the target circuit 101 and the heating circuit 103 are located within the package of the IC 100. Please refer to FIG. 2, which is a schematic diagram of an IC 100 according to one embodiment of the present invention. The IC 100 has a package 201 and a plurality of pins P_1, P_2 (only two pins are shown). Both the target circuit 101 and the heating circuit 103 are fabricated on the die which is cut from a wafer, and then disposed within the package 201 through steps such as adhesion, baking, and soldering. How to design, manufacture and package a circuit into an IC is well known, so details thereof are omitted for brevity.

Please refer to FIG. 1 again. In one embodiment, the testing portion 105 is only a portion of the target circuit 101. In one embodiment, after receiving the heating signal HS, the heating circuit 103 only heats the testing portion 105 and does not heat other circuits in the target circuit 101 other than the testing portion 105 (i.e., the other circuit is not the testing portion 105). In another embodiment, after the heating circuit 103 receives the heating signal, in addition to heating the testing portion 105, it also heats, in the target circuit 101, other circuits that are not the testing portion to a second predetermined temperature. The second predetermined temperature is lower than the first predetermined temperature. That is, the heating circuit 103 heats the testing portion to a higher temperature, while the non-testing portion can be heated to a lower temperature or not heated. In one embodiment, the target circuit 101 is a circuit with high temperature sensitivity, such as a clock oscillator. In another embodiment, the testing portion 105 is a portion with a higher temperature sensitivity in the target circuit 101, for example, a portion of the target circuit 101 comprising passive components (such as resistors, capacitors, inductors). The temperature sensitivity refers to a level that a parameter or characteristic of a circuit or a component changes in response to temperature. A circuit with a high temperature sensitivity is more likely to change its output current or voltage, or to change its impedance, capacitance or inductance value due to a high temperature, and may even be damaged due to a high temperature.

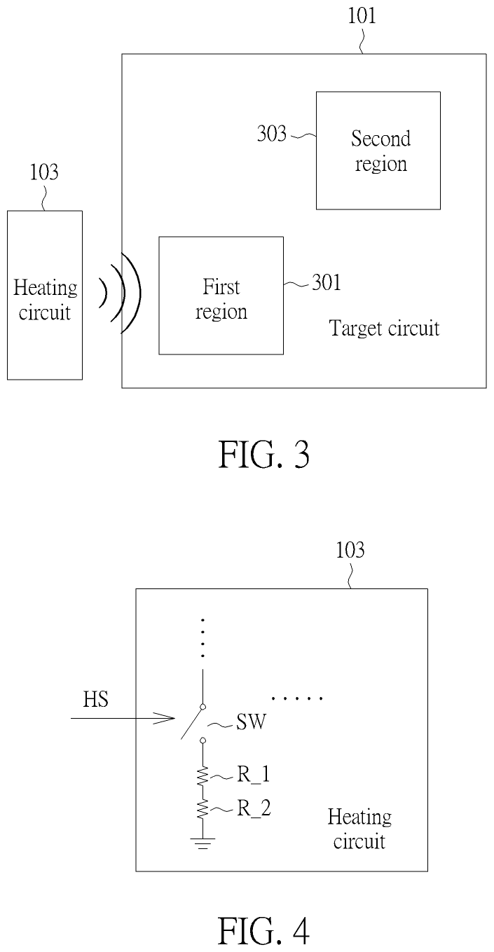

Specifically, as shown in the embodiment shown in FIG. 3, the target circuit 101 comprises a first region 301 and a second region 303. The first region 301 has a first temperature sensitivity and the second region 303 has a second temperature sensitivity. The first temperature sensitivity is higher than the second temperature sensitivity. In one embodiment, the first region 301 is the region with the highest temperature sensitivity in the target circuit 101. That is, the parameters or characteristics of the circuits or components in the first region 301 are more likely to change due to temperature than the parameters or characteristics of the circuits or components in the second region 303. Alternatively, circuits or components in the first region 301 are more likely to be damaged due to temperature than circuits or components in the second region 303. Therefore, when the heating circuit 103 receives the heating signal HS, it heats the first region 301 to test the first region 301. In such case, the first region 301 can be heated to a higher temperature and the second region 303 can be heated to a lower temperature or not heated by setting the position of the heating circuit 103 or its heating intensity.

The heating circuit 103 can be implemented by various circuits. In one embodiment, the heating circuit 103 comprises at least one resistor (two resistors R 1 and R 2 in this example) and at least one switch device (a switch device SW in this example). The switch device SW can be implemented by a circuit device such as a MOSFET (Metal-Oxide-Semiconductor Field-Effect Transistor), which controls whether the current flows through the resistors R 1 and R 2 according to the heating signal HS. When the switch device SW is turned on, at least one current flows through the resistors R 1 and R 2 to make the resistors R 1 and R 2 generate heat energy to heat the aforementioned testing portion. However, please note that the heating circuit 103 described in the present invention is not limited to the example in FIG. 4, and all circuit structures that can be controlled by signals to heat the testing portion 105 of the target circuit 101 should fall in the scope of the present invention.

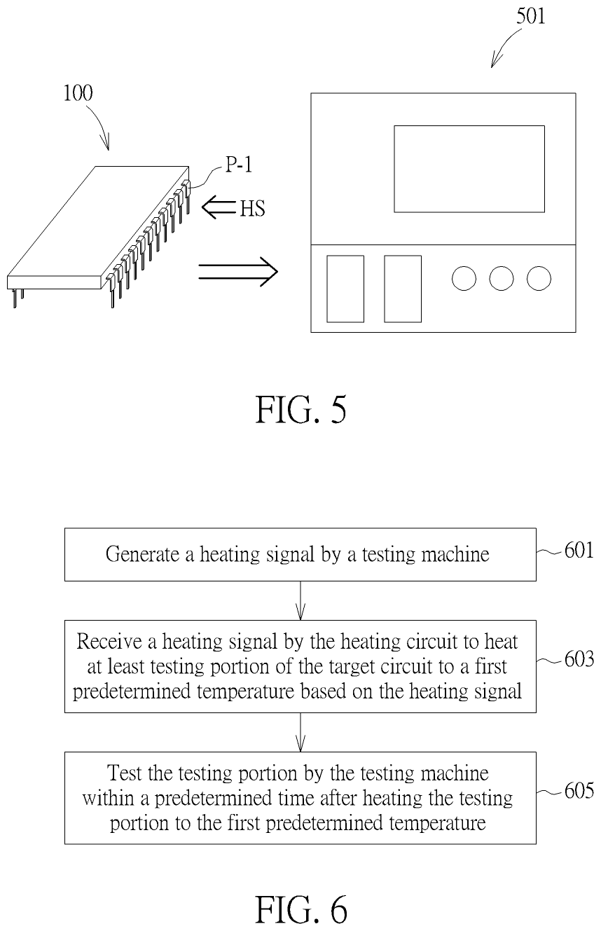

The following descriptions will illustrate a schematic diagram of how to test the IC provided by the present invention according to one embodiment. FIG. 5 is a schematic diagram illustrating an example for testing an IC provided by the present invention via a testing machine 501. However, please note that the testing machine is not limited to the form of the testing machine 501 shown in FIG. 5, and any testing machine that can achieve the same function should fall in the scope of the present invention. As shown in FIG. 5, when the IC 100 is to be tested, the IC 100 can be put into a testing machine 501. Different from the conventional IC testing method, the IC testing method provided by the present invention does not need to heat the entire IC 100, but only needs to use the testing machine 501 to generate the heating signal HS and send it to the heating circuit 103 of the IC 100, as illustrated in above-mentioned embodiments. By this way, the testing portion of the IC 100 can be heated to a predetermined temperature, so as to test the testing portion. In one embodiment, the heating signal HS is received by electrically connecting one of the pins of the IC 100 (for example, the pin P1_1) to the testing machine 501.

The testing machine 501 can also perform other tests to the IC 100, such as testing the withstand voltage of the circuit in the IC, or whether the current, voltage or signal conversion speed generated by the IC is within the required range. Therefore, after heating the testing portion to a predetermined temperature and testing the testing portion, while waiting for the testing portion to cool down to a normal temperature, other circuits other than the testing portions of the target circuit can be tested. The normal temperature may refer to a room temperature or another predetermined temperature, for example, the predetermined may refer to a temperature the temperature at which the IC can be safely removed from the testing machine 501. By such testing method, not only the high temperature test can be performed on the testing portion through a simple structure and steps, but other tests can also be performed while waiting for the testing portion to cool down. By this way, the testing time of the IC can be greatly reduced. In addition, since an IC testing machine always has the function of transmitting signals to the circuits inside the IC, after the IC manufacturer or IC packaging factory manufactures the IC and sends it to the IC testing factory, the IC testing factory can perform high temperature tests on ICs through common IC testing machines. There is no need to use dedicated heating machines or use other heating equipment to heat the entire IC. Moreover, since only a small portion of the IC needs to be heated, it is not necessary to provide large-scale heating which needs high power. Therefore, the IC and the IC testing method provided by the present invention can also reduce the cost of IC testing.

According to the above-mentioned embodiments, an IC testing method can be obtained. FIG. 6 is a flow chart illustrating an IC testing method according to one embodiment of the present invention, which is used to test an IC. The IC comprises a target circuit and a heating circuit (such as the IC 100, the target circuit 101, and the heating circuit 103 shown in FIG. 1). The IC testing method comprises the following steps:

### Step 601

Generate a heating signal (such as the heating signal HS) by a testing machine (such as the testing machine 501 in FIG. 5).

### Step 603

Receive a heating signal by the heating circuit to heat at least testing portion of the target circuit to a first predetermined temperature based on the heating signal.

For example, the first region 301 shown in FIG. 3 is heated.

### Step 605

Test the testing portion by the testing machine within a predetermined time after heating the testing portion to the first predetermined temperature

The predetermined time here can be set and managed according to different requirements. For example, it can be set to perform the test within 3 minutes after the testing portion is heated to the first predetermined temperature. In one embodiment, the testing portion is tested immediately after the testing portion is heated to the first predetermined temperature, that is, the predetermined time is zero. The predetermined time here can be set freely, for example, the predetermined time can be set corresponding to required time for each step in the entire IC testing process. As mentioned above, after the step 605, while waiting for the testing portion to cool down to a normal temperature, other circuits other than the testing portion of the target circuit can be tested. By this way, the overall testing time can be reduced.

In view of above-mentioned embodiments, a heating circuit with a simpler structure can be provided in the IC to heat the testing portion without heating the entire IC through other heating machines or heating equipment. Therefore, the IC and the IC testing method provided by the present invention can reduce the complexity of IC testing, reduce the time of IC testing, and reduce the cost of IC testing.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An integrated circuit (IC), comprising:
a package;
a target circuit; and
a heating circuit, configured to receive a heating signal and heat at least a testing portion of the target circuit to a first predetermined temperature based on the heating signal;
wherein the target circuit and the heating circuit are within the package.

2. The integrated circuit of claim 1, wherein the target circuit comprises:
a first region, having a first temperature sensitivity;
a second region, having a second temperature sensitivity, wherein the first temperature sensitivity is higher than the second temperature sensitivity;
wherein the heating circuit heats the first region responding to the heating signal.

3. The integrated circuit of claim 2, wherein the first region is a region which has a highest temperature sensitivity in the target circuit.

4. The integrated circuit of claim 1, wherein the heating circuit comprises at least one resistor, wherein the heating circuit performs heating via flowing at least one current through the resistor.

5. The integrated circuit of claim 4, wherein the heating circuit further comprises at least one switch device, to control the flowing of the current.

6. The integrated circuit of claim 1, wherein the target circuit is a clock oscillator.

7. The integrated circuit of claim 1, wherein the heating circuit does not heat other circuits of the target circuit responding to the heating signal, wherein the other circuits are not in the testing portion.

8. The integrated circuit of claim 1, wherein the heating circuit heats other circuits of the target circuit to a second predetermined temperature responding to the heating signal, wherein the other circuits are not in the testing portion, wherein the second predetermined temperature is lower than the first predetermined temperature.

9. An IC testing method, for testing an IC comprising a target circuit and a heating circuit, comprising:
(a) generating a heating signal by a testing machine;
(b) receiving a heating signal by the heating circuit to heat at least testing portion of the target circuit to a first predetermined temperature; and
(c) testing the testing portion by the testing machine within a predetermined time after heating the testing portion to the first predetermined temperature.

10. The IC testing method of claim 9, wherein the target circuit comprises:
a first region, having a first temperature sensitivity;
a second region, having a second temperature sensitivity, wherein the first temperature sensitivity is higher than the second temperature sensitivity;
wherein the heating circuit heats the first region responding to the heating signal.

11. The IC testing method of claim 10, wherein the first region is a region which has a highest temperature sensitivity in the target circuit.

12. The IC testing method of claim 9, wherein the heating circuit comprises at least one resistor, wherein the heating circuit performs heating via flowing at least one current through the resistor.

13. The IC testing method of claim 12, wherein the heating circuit further comprises at least one switch device, to control the flowing of the current.

14. The IC testing method of claim 9, wherein the target circuit is a clock oscillator.

15. The IC testing method of claim 9, further comprising:
testing other circuits of the target circuit when a temperature of the testing portion decreases to a normal temperature, after the step (c), wherein the other circuits are not in the testing portion.

16. The IC testing method of claim 9, wherein the heating circuit does not heat other circuits of the target circuit responding to the heating signal, wherein the other circuits are not in the testing portion.

17. The IC testing method of claim 9, wherein the heating circuit heats other circuits of the target circuit to a second predetermined temperature responding to the heating signal, wherein the other circuits are not in the testing portion, wherein the second predetermined temperature is lower than the first predetermined temperature.
